(19) United States
(12) Patent Application Publication
(10) Pub. No.: US 2024/0395576 A1
(43) Pub. Date: Nov. 28, 2024

(54) METHOD AND DEVICE FOR TRANSFERRING AND PREPARING COMPONENTS

(71) Applicant: EV Group E. Thallner GmbH, St. Florian am Inn (AT)

(72) Inventor: Jurgen Burggraf, St. Florian am Inn (AT)

(73) Assignee: EV Group E. Thallner GmbH, St. Florian am Inn (AT)

(21) Appl. No.: 18/694,015

(22) PCT Filed: Oct. 19, 2021
(86) PCT No.: PCT/EP2021/078910

§ 371 Date: Mar. 21, 2024

(51) Int. Cl. H01L 21/67; H01L 23/00

(52) U.S. Cl. CPC H01L 21/67132; H01L 24/83; H01L 24/97; H01L 2224/83; H01L 2224/97

(57) ABSTRACT

The invention relates to a method and a device for preparing components on a carrier substrate and a method and a device for transferring components from a carrier substrate onto a product substrate.

### FIELD OF THE INVENTION

The present invention relates to a method and a device for transferring components and a method and a device for preparing components. Components are understood in particular to mean electronic components, preferably functional components such as for example chips or MEMS. To this extent, invention relates to a method and a device for transferring or preparing very small components, which are aligned particularly precisely, transferred and processed.

The invention describes a method and a device for transferring a plurality of components, in particular chips, from a first substrate, a transfer substrate, onto a second substrate, a product substrate. Furthermore, the invention describes a method and a device for preparing a plurality of, in particular structurally identical, components on a transfer substrate.

### BACKGROUND OF THE INVENTION

In the prior art, the in particular electronic components are produced from a component substrate or on a substrate. These processes usually take place under atmosphere. In the atmosphere, the component surfaces are continuously exposed to reactive substances such as for example oxygen or nitrogen. When the components are being transferred and prepared, it is particularly important that their surfaces to be bonded are free from contaminating substances.

In the prior art, devices and methods are described, in which the component surfaces can be processed or cleaned free from oxygen compounds and/or nitrogen compounds. The processing and cleaning of the component surfaces partially take place in each case in a device which can operate under vacuum. However, the components are then removed again from this device and therefore exposed to the atmosphere. Subsequently, the components are then bonded onto a product substrate in another device. The component surfaces can again become contaminated along this path. As a result of the contamination, the number of defective components and the processing cost increases.

It is therefore an aim of the present invention to specify a method and device for transferring and preparing components, which at least partially eliminate, in particular completely eliminate, the drawbacks mentioned in the prior art. It is in particular an aim of the invention to specify an improved method and an improved device for transferring and preparing components. It is in particular an aim of the present invention to specify a method and a device for transferring and preparing components, which reduces the rejection rate of the components. Furthermore, it is an aim of the present invention to specify a method and a device for transferring and preparing components, which can be carried out, or operates, particularly reliably and free from contamination.

### SUMMARY OF THE INVENTION

The present problem is solved by the features of the coordinated claims. Advantageous developments of the invention are stated in the sub-claims. All combinations of at least two features stated in the description, in the claims and/or the drawings also fall within the scope of the invention. Values lying within the stated limits are also deemed to be disclosed as limiting values in the stated value ranges and can be claimed in any combination.

Accordingly, the invention relates to a method for preparing components on a carrier substrate with at least the following steps:
a1) preparation of a component substrate,
a2) application of a bonding layer onto a first surface of the component substrate, and then
b) separating the component substrate into components.
c) positioning of the components on a carrier substrate,
wherein the components are fixed on the carrier substrate with a first component surface comprising the bonding layer.

As a result of the application of the bonding layer in particular over the entire area on first surface of the prepared component substrate before separating of the component substrate into components, it is advantageously ensured that contamination is minimised. Application of the bonding layer on the carrier substrate is not therefore required in order to bond or fix the components on the carrier substrate. The application of a bonding layer on the carrier substrate can thus advantageously be dispensed with. As a result of the separation of the component substrate into components after the application of the bonding layer, it is ensured that the carrier substrate comes into contact only with the material of the bonding layer in the region of the components. Furthermore, it is advantageously ensured that no bonding material is present between the components positioned on the carrier substrate.

In this regard, less material of the bonding layer is used overall for the fixing of the components on the carrier substrate. In addition, when the processing of the components prepared on the carrier substrate is carried out, in particular processing over the entire area, it is ensured that no bonding layer is carried away into in gaps between the components or treated. Consequently, when the bonding layer is removed, contamination by the bonding material can also be reduced. Since the method is preferably carried out in a vacuum environment or under a vacuum, the reduction of contamination, in particular by the bonding material, is of particular importance.

Furthermore, it can be ensured during the positioning, preferably by means of a pick-and-place method, in step c) that the bonding layer is already provided on the components previously separated into single units. In this way, alignment marks on the carrier substrate can advantageously remain visible for the exact positioning of the components on the carrier substrate, since the latter are not concealed with a bonding layer. The carrier substrate is thus overall less contaminated. In the positioning in step c), all of the components or only a part of the separated components can be positioned on the carrier substrate. If not all of the components separated from the component substrate are positioned on the carrier substrate, the latter can for example either be transferred on another carrier substrate or, after a transfer or debonding of the previously positioned components from the carrier substrate, can be positioned or fixed on the same carrier substrate in a subsequent process step.

In a preferred embodiment of the method for preparing components on a carrier substrate, provision is made such that in step a2) a protective layer is also applied on a second surface of the component substrate. The protective layer can be applied on the component substrate before, during or simultaneously with the coating of the substrate side lying opposite with the bonding layer. The protective layer is applied before the components are separated into single units, so that components advantageously comprise the bonding layer and the protective layer. In this way, it can advantageously be ensured that the contamination, in particular of the carrier substrate and other components used in this process step, with the material of the protective layer is minimised. Especially during a subsequent removal of the protective layer from the components prepared on the carrier substrate, bonding layer is advantageously not removed, since no bonding layer is arranged on the carrier substrate in the gaps between the components and in addition the bonding layer applied on the first component surface is concealed by the components.

In a preferred embodiment of the method for preparing components on a carrier substrate, provision is made such that, in addition to the components, at least one supporting component is positioned on the carrier substrate in step c). The supporting component is in particular not a functional component. On the contrary, the supporting component is also positioned on the carrier substrate in order to prevent bending of the product substrate, in particular at the edge, in a subsequent bonding process.

In a preferred embodiment of the method for preparing components on a carrier substrate, provision is made such that the at least one supporting component is positioned outside a component positioning region on the carrier substrate. The component positioning region is a region on the carrier substrate on which the components previously separated into single units are positioned. This component positioning region is preferably arranged centrally on the carrier substrate or on a carrier substrate surface. The supporting components are particularly preferably positioned at an outer edge of the carrier substrate surface.

In a preferred embodiment of the method for preparing components on a carrier substrate, provision is made such that the least one supporting component is produced by separating the component substrate into single units in step b). In this way, the at least one supporting component can advantageously be produced or separated into single units with the components from the component substrate. The at least one supporting component thus advantageously also comprises the previously applied bonding layer. The at least one supporting component can thus also be positioned and fixed on the carrier substrate with in particular minimal contamination. The supporting component can thus be prepared in a particularly simple and efficient manner.

In a preferred embodiment of the method for preparing components on a carrier substrate, provision is made such that the at least one supporting component has the same height as the components. The at least one supporting component can thus support the outer regions of the product substrate and the carrier substrate particularly efficiently during a bonding process or during a transfer of the components. If the supporting component is jointly produced by the separation of the component substrate into single units in step b), it can thus be particularly advantageously ensured that the height of the supporting components corresponds to the height of the components. The height is to be understood in particular as the distance from the first component surface comprising the bonding layer up to the carrier substrate. The at least one supporting component particularly preferably also has the bonding layer.

In a preferred embodiment of the method for preparing components on a carrier substrate, provision is made such that at least two, preferably at least four supporting components, are positioned staggered uniformly outside the component positioning region. The supporting components are particularly preferably arranged staggered regularly around a periphery of the carrier substrate or around the edge of the component positioning region, so that a particularly uniform supporting effect can advantageously be brought about by the supporting components.

In a preferred embodiment of the method for preparing components on a carrier substrate, provision is made such that, after debonding the components from the carrier substrate, the at least one supporting component remains on the carrier substrate. When the components are debonded, the supporting components particularly preferably remain fixed or bonded on the carrier substrate. During the debonding from the carrier substrate, the components in the positioning region are released from the carrier substrate, so that the components are transferred to a product substrate. Due to the fact that the at least one supporting component remains on the carrier substrate, the carrier substrate can advantageously be reused.

Furthermore, the invention relates to a method for transferring components from a carrier substrate onto a product substrate with at least the following steps, in particular in the following sequence:
i) preparation, in particular according to the method for preparing components on a carrier substrate, of components on a carrier substrate, wherein the components each comprise a first component surface and each a second component surface, and wherein the components are fixed on the carrier substrate with the first component surface,
ii) processing of the second component surface of the components.
iii) bonding of the second component surface of the components on a product substrate.
   wherein steps ii) and iii) are carried out under a vacuum, characterised in that the vacuum is maintained between step ii) and step iii).

In the method for transferring components, the components are prepared on the carrier substrate particularly preferably using the method for preparing substrates on a carrier substrate. The free second component surfaces facing away from the carrier substrate are then processed. The processing of the component surfaces preferably comprises their cleaning, in particular cleaning free from oxide layers and other contaminating materials. The following bonding process is preferably introduced by contacting the component surfaces of all the components with a product substrate or with the surface of the product substrate.

As a result of advantageously maintaining the vacuum between the processing of the two component surfaces in step ii) and the bonding of the second component surface with the product substrate in step iii), the processed component surfaces are advantageously free from contaminating materials. The processed component surfaces do not therefore come into contact with an atmosphere before the bonding. The same applies particularly preferably to the carrier substrate. The processed surface of the components is thus particularly well suited for bonding on the product substrate. The processing can also include the removal of a protective layer, or comprise the removal of a protective layer. In this way, the bonding can be carried out particularly easily. In addition, the defect rate can thus be reduced or the number of defective components on the product substrate can be reduced. The vacuum lies under 1 mbar, more preferably under 10⁻⁵ mbar, most preferably under 10⁻⁹ mbar, with utmost preference up to 10⁻¹² mbar.

In a preferred embodiment of the method for transferring components from a carrier substrate onto a product substrate, provision is made such that the method for transferring components from a carrier substrate onto a product substrate according to step iii) additionally includes the following step:
iv) debonding of the components from the carrier substrate,
   wherein the debonding in step iv) is preferably carried out under a vacuum.

In the debonding, the components are in particular released or detached from the carrier substrate. The debonding preferably also takes place in a vacuum environment. Particularly preferably, the vacuum is also maintained between the bonding in step iii) and the debonding in step iv). As a result of the subsequent debonding of the components, in particular by weakening of the adhesive properties of a bonding layer applied between the first component surface and the carrier substrate, in a vacuum, contamination of the components or the component surfaces is advantageously further reduced.

In a preferred embodiment of the method for transferring components from a carrier substrate onto a product substrate, provision is made such that all the components are bonded simultaneously during the bonding in step iii). By maintaining the vacuum between the processing and the bonding, it is advantageously possible to bond all the components, preferably in parallel, onto the product substrate. Transferring of the components from the carrier substrate onto the product substrate is this enabled particularly efficiently and free from errors.

In a preferred embodiment of the method for transferring components from a carrier substrate onto a product substrate, provision is made such that, before the processing in step ii), the removal of a protective layer arranged on the second component surface is carried out. In combination with the processing and the immediately following bonding in the vacuum, a particularly contamination-free component surface can thus be prepared. The removal of the protective layer can in addition also be carried out immediately before the processing of the surfaces of the second component surfaces. Furthermore, the processing of the surface can also include the removal of the protective layer.

Furthermore, the invention relates to a device for preparing components on a carrier substrate according to the method for preparing components on a carrier substrate, characterised in that the device operates under a vacuum. Particularly preferably, the device operates completely under a vacuum, so that the carrier substrate and the components are not brought into contact with an atmosphere. The device preferably comprises a coating module and a separating module.

Furthermore, the invention relates to a device for transferring components from a carrier substrate onto a product substrate, wherein the device is designed such that the components prepared on the carrier substrate can be transferred, according to the method for transferring components from a carrier substrate onto a product substrate, from the carrier substrate onto the product substrate under a vacuum.

Particularly preferably, the device is designed to carry out all the operating steps under a vacuum. The components prepared on the carrier substrate can thereby be transferred onto the product substrate whilst maintaining the vacuum.

In a preferred embodiment of the device for transferring components from a carrier substrate onto a product substrate, provision is made such that the device is designed such that the carrier substrate bearing the components can be transferred from a surface treatment modular unit into a bonding modular unit whilst maintaining the vacuum. In this way, it can be ensured that contamination of the components, in particular of the second and treated component surfaces, is reduced. Markedly better bonding results can thus be achieved with the device.

An aspect of the invention includes bringing the components into a device or a modular system, aligning and bonding the components on the carrier substrate and not removing a protective layer until in the modular system, in order then to be able to clean the surface free for example from oxygen compounds and/or nitrogen compounds. The components are then preferably bonded still in the modular system with a product substrate and removed from the carrier substrate. i.e. separated by a debonding process. The method thus preferably relates to a parallel component transfer, in which a plurality of components are transferred simultaneously. The components preferably have the same dimensions, in particular the same height.

Moreover, a further aspect includes carrying out the method in a modular system in which the component surfaces are cleaned, without coming into contact again with a contaminating atmosphere, at least until the components make contact with the product substrate.

The component surfaces are thus in particular only cleaned free for example from oxygen compounds and/or nitrogen compounds when inside the modular system and are bonded onto a product substrate still in the modular system.

In an embodiment, individual components are aligned and highly precisely pre-fixed on a carrier substrate in order to be transferred simultaneously in a later process step onto a product substrate. The components are preferably first fixed by a pick-and-place system in a highly precise manner with respect to alignment marks on the carrier substrate. An alignment of a product substrate with the carrier substrate then takes place with further alignment marks specially provided for the purpose.

In an embodiment, the interface between the component and the product substrate is optically transparent and/or electrically conductive. These physical properties are guaranteed by a suitable surface treatment before bonding of the components on the product substrate. A further process step can be carried out for this or a further modular unit can be used. In general, the emerging interface can be regarded as optically and/or mechanically and/or thermally and/or electrically ideal. Ideal means that the best possible optical and/or mechanical and/or thermal and/or electrical properties that can be achieved are achieved by the surface treatment, in particular by the removal of harmful oxides and/or nitrides.

Mechanically ideal means that the mechanical properties, in particular the bonding strength, of the interface enable an adhesion as efficient as possible between the component and the product substrate. In particular for hydrophilic fusion bonding, which preferably takes place by the contacting of an oxide surface on the component and/or an oxide surface on the product substrate, the bonding strength between the component and the product substrate is characterised with the aid of the surface energy that is required to separate a unit area from a square metre. The bonding strength is in particular greater than 0.5 J/m2, preferably greater than 1.0 J/m2, still more preferably greater than 1.5 J/m2, most preferably greater than 2.5 J/m2, with utmost preference greater than 2.5 J/m2.

Optically ideal means that electromagnetic radiation can pass through the interface in the best possible manner, i.e. preferably without or with very little loss of intensity. The transmissivity is in particular greater than 10%, preferably greater than 50%, preferably greater than 75%, most preferably greater than 95%, with utmost preference greater than 99%.

Thermally ideal means that a heat flow can pass through the interface in the best possible manner, i.e. preferably without or with very little loss of heat. The heat loss is in particular less than 50%, preferably less than 25%, preferably less than 10%, most preferably less than 5%, with utmost preference less than 1%.

Electrically ideal means that the electrical conductivity via the interface is as high as possible. The electrical conductivity should be greater than 1 S/m, preferably greater than 10 S/m, preferably greater than 102 S/m, most preferably greater than 104 S/m, with upmost preference greater than 106 S/m. If the surfaces of the components and/or the regions of the product substrate on which the components are bonded are hybrid surfaces, the data for the electrical conductivity applies only to the electrical regions.

In a preferred embodiment, the components are coated with a bonding layer before separation into single units, so that after the bonding of the components on a carrier substrate, no bonding material is present between the components which could unnecessarily contaminate the modules of the modular system.

In another embodiment, components are located at the edge of the carrier substrate, the purpose of which is to prevent the peripheral bending of the product substrate during bonding onto the components in the component positioning region during bonding. In particular, a corresponding carrier substrate can already be prefabricated with components for the pressure absorption and introduced into a modular system. In this special embodiment, it is particularly helpful if the components for the pressure absorption are permanently connected to the carrier substrate. In a further embodiment of the latter, the components for the pressure absorption can however also be produced from or on the same component substrate, out of or from which the preferably functional components actually to be transferred for positioning in the component positioning region are produced. In this case, it is conceivable that the components for the pressure absorption are also transferred during the transfer of the components from the carrier substrate onto the product substrate.

### Component

Within the scope of the invention, a component is understood to be an in particular functional object which is bonded onto a substrate. The components are preferably a chip, a MEMS, an LED, a microchip or similar components. Components are preferably produced from a component substrate. It is also conceivable for the components to be produced on a substrate. The component either itself has component alignment marks or geometrical characteristics such as corners, lines or structures on the component are used as component alignment marks.

### Component for Pressure Absorption

A component for pressure absorption or a supporting component is understood within the scope of the invention to mean a component which can be arranged or is prepared on the carrier substrate with a stabilising mechanical function. In contrast with the components actually to be transferred, it performs in particular a stabilising task for the transfer and bonding process. Particularly preferably, it has the same height as the components to be transferred and can be produced together with the components. Components for the pressure absorption are preferably positioned and in particular bonded at the periphery, in particular in a region of the carrier substrate lying outside the centre-point of the substrate holding surface. Supporting components prevent a product substrate, which makes contact with the components pre-fixed on the carrier substrate, from becoming bent at its periphery. Since the components to be transferred are generally not distributed over the entire surface of the carrier substrate, but rather are fixed only in a component positioning region, the use of components for pressure absorption is particularly preferred.

### Component Substrate

A component substrate is understood to mean a substrate which serves for the production of components. The functional regions of the subsequent components are preferably produced in a wafer-level process. In this process, a plurality of process steps can be carried out in order to be able to guarantee the functionality of the subsequent component. The component substrate is separated into single units in particular at the end of the process. This separation of the component substrate into the components and, as the case may be, into the supporting component takes place for example by means of a saw, a wire, a laser or similar aids.

### Carrier Substrate

A carrier substrate is understood to mean a substrate, relative to which the components are aligned and temporally bonded. It serves in particular exclusively for the temporary mounting of the components or the supporting components. The carrier substrate preferably has a plurality of alignment marks along the carrier substrate surface, which are used for the alignment of the components relative to the carrier substrate. These alignment marks can therefore also be referred to as component alignment marks. Furthermore, the carrier substrate has alignment marks in order to be able to align the carrier substrate relative to the product substrate. These further alignment marks can thus also be referred to as substrate alignment marks. In an embodiment, the carrier substrate already has one or more components for the pressure absorption or supporting components. These supporting components are preferably permanently connected to the carrier substrate. The carrier substrate can advantageously be made from any material. Once the method for preparing components has been carried out, a bonding layer on the carrier substrate can also be advantageously dispensed with.

### Product Substrate

The product substrate is the substrate onto which the components are transferred from the carrier substrate. The product substrate has alignment marks in order to be able be aligned relative to the carrier substrate. These alignment marks can, as in the case of the carrier substrate, be referred to as substrate alignment marks.

### Modular System

A modular system, sometimes also referred to as a vacuum device or cluster, is understood to mean a number of associated modules or modular units. A vacuum can preferably be generated or provided in the modules. A particularly preferred feature of the proposed modular system is that the substrates are not exposed to the atmosphere between different process steps and it is thus possible to operate constantly under a vacuum. Once a substrate is inside the modular system, it is further treated or prepared in particular under an optimum vacuum environment. All the modules of the modular system can preferably be evacuated individually. Particularly preferably, the modular system comprises at least one lock for introducing the substrates or for preparing the components.

Several special modules are described in the following text, which are preferably part of the devices or of the modular system, in order to be able to constitute the devices or to carry out the processes. The modules are therefore listed in particular in the order of use in the method.

The transport of substrates or substrate stacks in the modular system preferably takes place by means of a robot, which is located in the centre of the modular system or can move correspondingly along a rail system.

### Coating Module

If the modular system or the devices for the transfer or the preparation comprise a coating module, the bonding layer and/or the protective layer can be applied on the component substrate.

The coating module is optional. It is also conceivable for example that the component substrate is coated with the bonding layer and/or the protective layer outside the modular system and then introduced into the modular system. This is advantageous particularly when the producer of the functionalised component substrate provides the component substrate immediately after the functionalisation of the protective layer. If a coating module is present in the modular system, at least one bonding layer can be applied therewith. The latter can, in contrast with the protective layer, become contaminated during the transport from the producer of the functionalised component substrate to the modular system.

### Separating Module

If the modular system comprises a separating module, the component substrate can be separated into single units in the modular system. It would also be conceivable for the separation into single units also to take place outside the modular system and to deliver the already separated components into the modular system. Especially when use is made of the method for preparing components or when use is made of a device for preparing components, in which a bonding layer is applied on the component substrate before the separation into single units, a separating module inside the modular system is advantageous.

### Pick-and-Place Module

The pick-and-place module has the task of aligning, positioning and bonding or fixing the individual components on the carrier substrate. Especially in the case of the coating of the component substrate with a bonding layer before the separation into single units, the pick-and-place module can easily take up, align, position and bond or fix the components. In this case, it is advantageous that no bonding material is present between the components prepared on the carrier substrate.

If the carrier substrate itself has been coated with the bonding layer over the entire surface, the components are bonded directly on the bonding layer on the carrier substrate. In this case, bonding material is disadvantageously present between the components, which causes undesired additional contamination in a module that is subsequently passed through.

### Cleaning Module

The cleaning module serves to remove the protective layer from the components. It is conceivable for the cleaning module to be located outside the modular system. In this case, the components would be delivered into the modular system without the protective layer. In a particularly preferred embodiment, the cleaning module is however also part of the modular system.

### Surface Treatment Module

The surface treatment module or the surface treatment modular unit is part of the modular system or of the device for transferring components. The surface treatment module is thus the part of the modular system in which the component surfaces freed from the protective layer are treated. It is however also conceivable that a cleaning module is integrated in the surface treatment module. The treatment or processing of the component surfaces is understood in particular to mean a removal of interfering material, in particular oxygen compounds and/or nitrogen compounds. Since the first component surfaces are still more reactive after the removal of oxygen compounds and/or nitrogen compounds and should no longer be exposed to the atmosphere before contacting with the product substrate, the surface treatment module is preferably a part of the modular system. The surface treatment module can for example be a plasma chamber or an ion beam chamber. It is preferably an ion beam chamber, as in publication WO2015197112A1.

It is also conceivable for an activation of the component surfaces to take place in the surface treatment module. Furthermore, it is conceivable for a hydrophilisation of the component surfaces to take place in the surface treatment module. In addition, it is conceivable for special layers to be applied in the surface treatment module, which improve the bond between the components and the product substrate.

### Bonding Module

After the component surfaces have been treated or processed in the surface treatment module, the bonding of a product substrate with the treated component surfaces takes place. For this purpose, the product substrate is aligned relative to the carrier substrate and bonded. The alignment preferably takes place using alignment marks, which are located on the carrier substrate and the product substrate. The bonding module therefore preferably has, particular preferably, an optical alignment system. Furthermore, the bonding module comprises a device for contacting of the product substrate with the components or the component surfaces facing the product substrate.

### Debonding Module

After the contacting of the product substrate with the components, the connection between the components and the carrier substrate is preferably weakened or completely removed. This preferably takes place in a separate debonding module or a debonding modular unit. It is also conceivable for corresponding debonding devices to be integrated in the bonding module, so that the carrier substrate-component-product substrate stack does not have to be transported into a further module.

The method described in the following comprises important process steps. Individual process steps of the method for transferring and preparing the components are described in the exemplary methods. In this regard, the exemplary methods form aspects of the method for transferring and the method for preparing the components. The expert in the field knows that there are certainly a number of further, not explicitly mentioned, process steps that can be part of the method. Since the latter are not important for an understanding of the exemplary method and in part also cannot be unequivocally determined an advance, the exemplary methods are described solely on the basis of the following process steps.

### Exemplary Methods

In a first process step of the exemplary method, the coating of the first component substrate surface with a protective coating and the coating of the second component substrate surface with a bonding layer take place. The bonding layer preferably permits bonding between room temperature and approx. 300° C. Furthermore, the bonding layer should preferably have no or only very little outgassing. The thickness of the bonding layer lies between 1 nm and 100 μm, preferably between 1 nm and 50 μm, more preferably between 1 nm and 10 μm, most preferably between 1 nm and 1 μm, with utmost preference between 1 nm and 100 nm. The bonding layer has the important task of keeping the components in position until the components are bonded, with their side lying opposite the bonding layer, on the product substrate.

In a second process step of the exemplary method, a component substrate is separated into individual components. The separation takes place in particular with the aid of a saw and/or a wire and/or a laser and/or a particle—in particular an ion beam. It is an important aspect of the method for preparing components the bonding layer is applied on the component substrate before the separation into single units. In the prior art, the bonding layer is very often applied on the carrier substrate. In the subsequent fifth process step, the cleaning step, this thus leads to a contamination of the . . . .

In a third process step of the exemplary method, an alignment and a bonding process of at least one component, preferably all the components takes place in respect of a carrier substrate. The alignment of the components in respect of the carrier substrate takes place in particular in relation to alignment marks, which are located on the carrier substrate. Exact positioning of the components with respect to the carrier substrate is thus enabled. The alignment preferably takes place with the aid of optical systems. In the bonding process, the components are then contacted with the carrier substrate.

In a fourth process step of the exemplary method, the protective layers are removed from the first component surfaces, so that the first component surfaces are freed. This process step takes place in particular in a separate cleaning module.

In a fifth process step of the exemplary method, the first component surfaces are cleaned. In particular, cleaning is understood to mean a removal of oxygen compounds and/or nitrogen compounds. This cleaning preferably takes place under vacuum, i.e. in a vacuum device, in particular in a separate module. It is also conceivable for the fourth and fifth process step to be carried out in the same module, in particular also with the same device. For this purpose, however, the device must be designed such that it can remove the protective layer and the oxygen compounds and/or nitrogen compounds. Since the protective layer on the one hand and the oxygen compounds and/or the nitrogen compounds on the other hand are generally made from different materials, it is preferred for the two process steps to be carried out in different modules.

In a sixth process step of the exemplary method, the product substrate is bonded onto the components of the carrier substrate. The alignment of the product substrate relative to the carrier substrate takes place with the aid of substrate alignment marks.

In a seventh process step of the exemplary method, the product substrate is lifted from the carrier substrate. The components remain on the product substrate, since the permanent bond between the first component surface and the product substrate surface is stronger than the temporary bond between the second component surface and the carrier substrate surface. In particular, the detachment of the components from the carrier substrate can be assisted by a debonding process. A thermal effect is conceivable, in particular to soften a bonding layer, or the effect of electromagnetic radiation, in particular of a laser.

### Modified Method

By means of a modification of the exemplary method, the modified method arises. The latter differs by the fact that the application of a bonding layer on the component substrate according to the second process step is dispensed with. Instead, a bonding layer is applied on the carrier substrate, in particular over the whole surface. A drawback with this method is that the exposed bonding material can contaminate the following modules of the method that are passed through. Since a bonding material is most often an organic polymer, the contamination with this organic polymer is undesired. Especially in the modules in which the cleaning and removal of the oxygen compounds and/or the nitrogen compounds takes place, a very large proportion of bonding material between the bonded components can be removed by the following process steps and can contaminate the modules and thus the components. This modified method is only mentioned for the sake of completeness and is less preferred than the exemplary methods.

### BRIEF DESCRIPTION OF THE DRAWINGS

Further advantages, features and details of the invention emerge from the following description of preferred examples of embodiment and with the aid of the drawings. Diagrammatically:

FIG. 1a shows a first process step of the exemplary method.

FIG. 1b shows a second process step of the exemplary method.

FIG. 1c shows a third process step of the exemplary method.

FIG. 1d shows a fourth process step of the exemplary method.

FIG. 1e shows a fifth process step of the exemplary method.

FIG. 1f shows a sixth process step of the exemplary method.

FIG. 1g shows a seventh process step of the exemplary method.

FIG. 2 shows a plan view of an exemplary carrier substrate.

FIG. 3 shows a plan view of an exemplary modular system and

FIG. 4 shows a carrier substrate with prefixed supporting components.

### DETAILED DESCRIPTION OF THE INVENTION

Identical components or components with the same function are denoted by the same reference numbers in the figures. These parts are represented neither true to scale nor true to proportion. In particular, components 4 and supporting components 4′ are represented much thicker in order to improve the representation. The relatively thin alignment marks 5, 5′, 5″ are also represented thicker. All the figures are schematic representations.

The exemplary method is carried out under vacuum in a modular system, sometimes also referred to as a cluster, which can be evacuated. The modular system is preferably designed such that all the modules are connected to one another and can be evacuated throughout, so that carrier substrate 6, product substrate 8 and components 4, 4′ preferably also no longer come into contact with an atmosphere, until the method is completely finished.

In a very particularly preferred embodiment, the exemplary method is already carried out from the first process step in the mentioned modular system. In this case, the modules which are responsible for the coating and the separation into single units must be able to be separated as well as possible from the other modules, so that contamination of other modules as far as possible is avoided or at least minimised, since the separation of component substrate 1 into components 4, 4′ is in particular accompanied by a considerable quantity of particles.

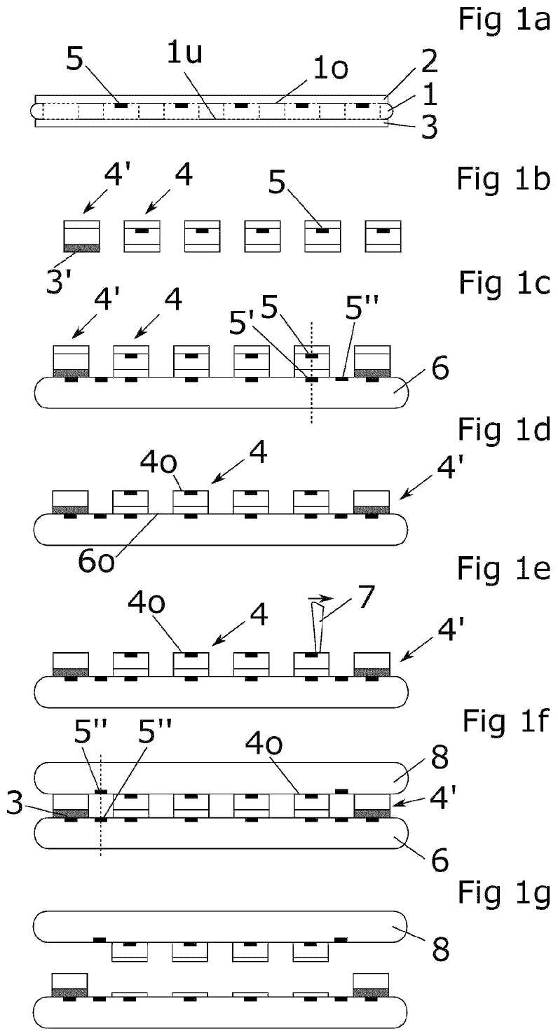

FIG. 1a shows a first process step of the exemplary method, in which a component substrate 1, which serves as the initial substrate for subsequently produced components 4, is coated on both sides. Component substrate 1 preferably already comprises alignment marks 5, with the aid of which subsequently produced components 4 can be correctly positioned. Components 4 in their state not yet separated into single units are preferably already functionalised, i.e. have all the necessary properties. It would also be conceivable for example for components 4 to be microchips. In this case, all the circuits would already be produced in component substrate 1. If the components are MEMS, all the mechanical components and/or electrical components have been produced. A protective layer 2 is applied on a component substrate surface 1o. Bonding layer 3 is applied on a component substrate surface 1u. The application of bonding layer 3 takes place before the separation into single units in process step 2 (see FIG. 1b).

FIG. 1b shows a second process step of the exemplary method, in which a separation of component substrate 1 into individual components 4 takes place. Components 4′ can be produced from substrate component 1, from which components 4 are produced, or any other substrate (not shown) with corresponding necessary physical, in particular mechanical, properties. Components 4′ can be used in a subsequent process step as supporting components. Components 4′ can also comprise alignment marks 5. In order to distinguish them from actual functional components 4 and because their positioning does not have to take place as exactly as the positioning of components 4, the representation of alignment marks on components 4′ is dispensed with. Components 4′ generally comprise another bonding layer 3′, which preferably permanently connects it to carrier substrate 6 (see FIG. 1c). It is however also conceivable for bonding layers 3, 3′ to be identical. In this case, components 4′, which should have a preferably supporting effect, can be transferred onto subsequent product substrate 8 just as components 4. For the sake of generality, however, it is assumed in the following text that components 4′ remain fixedly connected to carrier substrate 6. Components 4′ preferably have the same thickness as components 4, wherein the height of all the components 4, 4′ is particularly preferably the same with respect to carrier substrate surface 6o.

FIG. 1c shows a third process step of the exemplary method, in which carrier substrate 6 is provided with individual components 4, 4. Components 4 preferably comprise alignment marks 5. Components 4 are then preferably aligned using their alignment marks 5 relative to alignment marks 5′, which are located on carrier substrate 6. Alignment marks 5′ serve especially for the alignment of components 4. Alternatively, geometrical features of components 4, in particular their corners and edges, can be used for the alignment. After and/or during the alignment, contacting of components 4, 4′ with carrier substrate 6 takes place. Alignment marks 5″ are also located on carrier substrate 6, in respect of which product substrate 8 is aligned in subsequent process steps. Components 4′ can be positioned especially at the edge of carrier substrate 6, which components have a supporting effect in a subsequent process step. The positioning of components 4 can also take place with alignment marks 5 (not shown). It is also conceivable, however, to provide carrier substrate 6 with components 4′ without an alignment process. Components 4′ are preferably positioned at at least two points, still more preferably at at least three points, most preferably at at least four points of carrier substrate 6, in order to guarantee an optimum supporting effect.

FIG. 1d shows a fourth process step of the exemplary method, in which a cleaning step of component surface 40 takes place. Component surface 40 can be cleaned free from protective layer 2 by means of any method. Wet-chemical methods for example are conceivable. If protective layer 2 is a solid layer, in particular a dielectric, preferably an oxygen compound and/or a nitrogen compound, a removal can then take place by an ion beam or in general by sputtering. As a result of the particularly preferred aspect of applying bonding layer 3 (see FIG. 1a) on component substrate 1 already before the separation process (see FIG. 1b), the particularly preferred effect arises that carrier substrate surface 6o is free from bonding material at the points at which no components 4, 4′ have been positioned. As a result, the modules of modular system 9 (see FIG. 3) do not become unnecessarily contaminated. The feature of the coating of component substrate 1 with a bonding layer 3 before the separating process therefore represents an important aspect.

FIG. 1e shows a fifth process step of the exemplary method and thus the surface treatment. Surface treatment can be understood to mean a removal of oxygen compounds and/or nitrogen compounds and/or surface activation and/or deposition of a layer for the bonding of components 4 with product substrate 8 made available in the subsequent process. This process step can in particular be carried out simultaneously with the preceding process step, if protective layer 2 is an oxygen compound and/or nitrogen compound.

Since the exemplary method already takes place in a modular system (see FIG. 3), the (second) component surface 40 cannot contaminate again after the removal of oxygen compounds and/or nitrogen compounds. The removal of oxygen compounds and/or nitrogen compounds can take place with any process suitable for the purpose or any device suitable for the purpose. Particularly preferably, however, removal of the oxygen compounds and/or the nitrogen compounds is by means of a particle beam, in particular an ion beam. Analogous considerations apply to a nitrogen removal.

Especially during and/or after a removal of oxygen compounds and/or nitrogen compounds, activation of the surface can take place. An intentional hydrophilisation of component surface 40 is also conceivable, in order to improve the so-called pre-bond between components 4 and subsequent product substrate 8.

It is also conceivable that special, organic and/or inorganic, layers are deliberately deposited in order to produce a connection between component 4 and product substrate 8. In particular, component 4 comprises a preferably native oxide. In a particularly preferred embodiment, component 4 has a hybrid bonding surface. A hybrid bonding surface is a surface predominantly including oxide, in which metallic regions, in particular of copper, are located. The metallic regions represent the contact points for the electrical contacting with the functional regions of component 4.

Especially in the case of a direct bond between component 4 and a product substrate 8, the interface thus arising can, with suitably selected materials, be optically transparent and/or electrically conductive. It is also conceivable for electrical and dielectric regions to be located on component surface 40 and on product substrate 8, which bonded together in each case. The electrical regions are preferably contacting points, which produce an electrically conductive connection between product substrate 8 and component 4. These bonds between two components, which have electrical and dielectric regions or surfaces, are called hybrid bonds. Their detailed structure and use are known to the person skilled in the art and are not explained in detail here. It is however disclosed that the method is suitable and even designed especially for the production of hybrid bonds.

FIG. 1f shows a sixth process step of the exemplary method, in which a product substrate 8 is aligned relative to a carrier substrate 6 and contacted. The force with which product substrate 8 presses on components 4, 4′ and therefore carrier substrate 6 lies between 1N and 100 kN, preferably between 1N and 10 kN, still more preferably between 1N and 1 kN, most preferably between 1N and 100N, with utmost preference between 1N and 10N. Small forces are therefore preferred in order as far as possible not to damage components 4, 4′ and/or product substrate 8.

The alignment takes place by means of alignment marks 5″ of carrier substrate 6 and product substrate 8. Provided components 4′ can act as supporting components in this contacting process. This process step can optionally also be followed by a process step in which the adhesive effect between component surface 4o and product substrate surface 80 is increased. A heat treatment step at more than 50° C. preferably more than 75° C. still more preferably more than 100° C. most preferably more than 150° C. for example, is conceivable. Preferably, however, the direct contacting should generate an adhesion which is strong enough to separate components 4 in the next process step along bonding layer 3. A temperature treatment can then preferably be dispensed with, which would be disadvantageous, since the material of bonding layer 3 could outgas.

FIG. 1g shows a seventh process step of the exemplary method, in which the separation of product substrate 8 from carrier substrate 6 takes place.

In an embodiment, the separation can take place purely mechanically. Use is made of the fact that the adhesive effect of component 4 relative to product substrate 8 is greater than the static friction of the components with respect to carrier substrate 6.

Alternatively and preferably, the bonding layer between component 4 and carrier substrate 6 can be weakened. This weakening can take place over the whole area or selectively per component 4.

A thermal action on bonding layer 3 by means of a heat treatment of all the components, for example in a furnace, is conceivable.

Alternatively, a selective thermal action, in particular by means of a laser, is conceivable. The laser is selectively focused on the bonding layer and weakens the latter. The wavelength of the laser used lies between 140 nm and 6000 nm. i.e. includes lasers with wavelengths in the UV region up to the infrared region. The precisely used laser wavelength depends on the material used for bonding layer 8.

The use of electromagnetic radiation is conceivable, which weakens the adhesion of bonding layer 3 by the fact that bonds of the macromolecules are broken.

Alternatively, it is conceivable that the adhesion of bonding layer 3 is reduced by microwave radiation.

When product substrate 8 is removed, bonding layer 3 preferably and generally remains partially on components 4 and partially on carrier substrate 6 and can be removed in a subsequent cleaning step.

At the end of this process step, a plurality of components 4 are obtained on a product substrate 8.

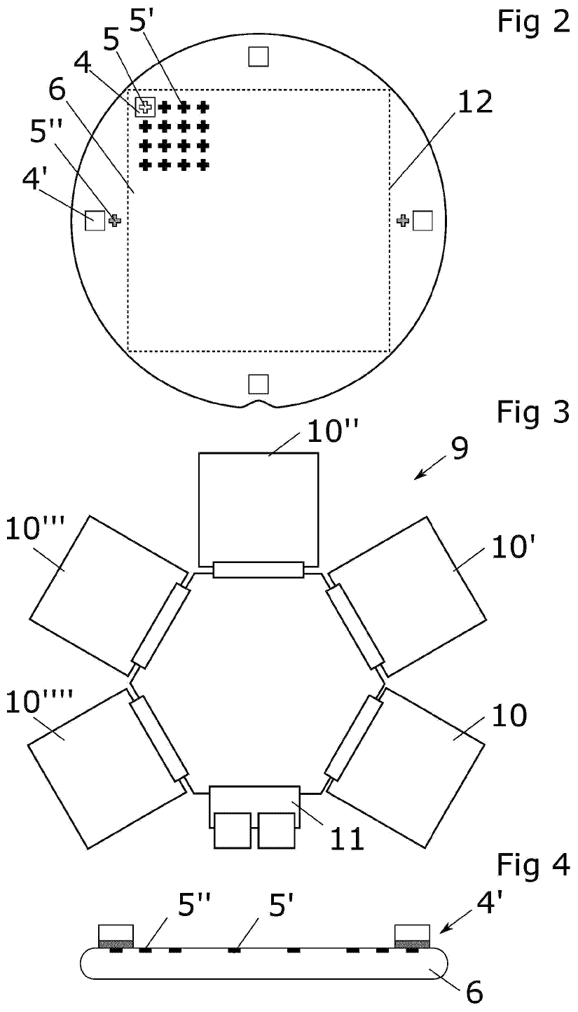

FIG. 2 shows a plan view of a carrier substrate 6. On carrier substrate 6 there are for example four components 4′, which serve as supporting components. They have a supporting effect in the process step according to FIG. 1e. A plurality of alignment marks 5′ are present distributed over carrier substrate 6. By way of example, sixteen alignment marks 5′ have been shown. First alignment mark 5′ is concealed by a component 4 with an alignment mark 5. A further two alignment marks 5″ are located on carrier substrate 6, which are used for the alignment of carrier substrate 6 with respect to product substrate 8 (not shown, see FIG. 1e). Alignment marks 5 (white), 5′ (black) and 5″ (grey) have been coloured differently for the sake of clarity, in order to assist a clear illustration. Components 4 are positioned and bonded exclusively in a component positioning region 12. If in the sixth process step (see FIG. 1f) a product substrate 8 is bonded onto components 4 and if components 4 were not located on carrier substrate 6, product substrate 8 could be pressed at the periphery in the direction of carrier substrate 6 and in the worst case even break in the presence of an excessively great application of pressure. By using components 4′ as supporting elements, this can be prevented. Components 4′ therefore represent an important aspect.

FIG. 3 shows a plan view of an exemplary modular system 9, including a plurality of modules 10, 10′, 10″, 10′″, 10″″. The number of modules is arbitrary. For example and without restriction, modules 10, 10′, 10″, 10′″, 10″″ are designed as follows. Module 10 represents a coating module, in which bonding layer 3 and/or protective layer 2 can be applied (see FIG. 1a). Module 10′ represents a separating module, in which component substrate 1 can be separated into single units (see FIG. 1b). Module 10″ represents an alignment and bonding module, in which individual components 4, 4′ can be aligned and positioned on carrier substrate 6. In this module, therefore, a type of pick-and-place device is preferably present. Module 10′″ represents a cleaning module, in which protective layer 2 can be removed. Module 10″″ represents an alignment and bonding module, in which the substrates, in particular carrier substrate 6 provided with components 4, 4′ and a product substrate 8, can be aligned with one another and bonded with one another. A task can also be completed by a module, if the necessary devices are present in the module. It is also conceivable for modular system 9 to comprise further modules. In particular the coating and the separation into single units can also take place outside modular system 9, so that only the already separated components 4, 4′ are introduced into modular system 9. In this case, the two aforementioned modules 10, 10′ could be left out, it is important that modular system 9, in particular the individual modules amongst one another, permit the transfer of components 4, 4′ and substrates 6, 8, without exposing the latter to the atmosphere.

Entire modular system 9 can thus be evacuated and can be sealed off from the surrounding atmosphere. The loading and unloading of all the necessary objects preferably takes place via a lock 11, so that the interior of modular system 9 can preferably remain evacuated as long as possible.

Modular system 9 or individual modules 10, 10′, 10″, 10′″, 10″″ can be evacuated to a pressure less than 1 bar, preferably less than 1 mbar, still more preferably less than 10⁻⁵ mbar, most preferably less than 10⁻⁹ mbar, with utmost preference up to 10⁻¹² mbar. These data correspond to the proposed values of the prevailing vacuum.

FIG. 4 shows a side view of a prefabricated carrier substrate 6, with already provided components 4′, which serve in the exemplary method for stabilisation and pressure distribution. Such a prefabricated carrier substrate 6 can be loaded into a modular system 9 and used immediately. Especially when components 4, according to the exemplary method, have already been coated with bonding layer 3 before their separation into single units, prefabricated carrier substrate 6 can be quickly provided with further components 4. After the transfer of components 4 onto product substrate 8 (see FIG. 1g), carrier substrate 6, in particular after cleaning, can be reused.

### LIST OF REFERENCE NUMBERS

1 component substrate
1o (second) upper component substrate surface
1u (first) lower component substrate surface
2 protective layer
3 bonding layer
4, 4′ component, supporting component
4o component surface
5, 5′, 5″ alignment mark
6 carrier substrate
6o carrier substrate surface
7 surface treatment means
8 product substrate
9 modular system
10, 10′, 10″, 10′″, 10″″ module
11 lock
12 component positioning region

1. A method for preparing components on a carrier substrate, comprising:
preparing a component substrate,
applying a bonding layer onto a first surface of the component substrate, and a protective layer onto a second surface of the component substrate,
separating, after the applying of the bonding layer and the protective layer, the component substrate into components, and
positioning the components on a carrier substrate,
wherein the components are fixed on the carrier substrate with a first component surface including the bonding layer.

2. (canceled)

3. The method according to claim 1, further comprising, during the positioning of the components:
positioning one or more supporting components on the carrier substrate in order to prevent bending an edge of the product substrate during bonding of the product substrate with the components.

4. The method according to claim 3, wherein the supporting components are positioned outside a component positioning region on the carrier substrate.

5. The method according to claim 3, wherein the separating of the component substrate produces the supporting components.

6. The method according to claim 3, wherein each of the supporting components has a height that is equal to heights of the components.

7. The method according to claim 3, wherein at least two of the supporting components are positioned staggered uniformly outside the component positioning region.

8. The method according to claim 3, further comprising:
debonding the fixed components from the carrier substrate,
wherein, after the debonding of the fixed components, the supporting components remain on the carrier substrate.

9. A method for transferring components from a carrier substrate onto a product substrate, comprising:
preparing the components on the carrier substrate, each of the components including a first component surface and a second component surface, the preparing of the components comprising:
preparing a component substrate,
applying a bonding layer onto a first surface of the component substrate and a protective layer onto a second surface of the component substrate,
separating, after the applying of the bonding layer and the protective layer, the component substrate into the components, and
positioning, after the separating of the component substrate, the components on the carrier substrate, the components being fixed on the carrier substrate with the first component surface including the bonding layer,
processing, after the positioning of the components, the second component surface of each of the components, and
bonding, after the processing of the second component surface, the second component surface of each of the components on a product surface.

10. The method according to claim 9, further comprising, after the bonding of the second component surface:
debonding the components from the carrier substrate,
wherein the debonding of the components is carried out under vacuum.

11. The method according to claim 9, wherein the components the components are bonded simultaneously in the bonding of the second component surface.

12. The method according to claim 9, further comprising, before the processing of the second surface:
removing the protective layer from the second component surface.

13. A device for preparing substrates on a carrier substrate, comprising:
means for preparing a component substrate,
means for applying a bonding layer onto a first surface of the component substrate and a protective layer onto a second surface of the component substrate,
means for separating, after the applying of the bonding layer and the protective layer, the component substrate into components, and
means for positioning the components on the carrier substrate,
wherein the components are fixed on the carrier substrate with a first component surface including the bonding layer.

14. The device for transferring components from a carrier substrate onto a product substrate, comprising:
means for preparing the components on the carrier substrate, each of the components including a first component surface and a second component surface, the means for preparing the components comprising:
means for preparing a component substrate,
means for applying a bonding layer onto a first surface of the component substrate and a protective layer onto a second surface of the component substrate,
means for separating, after the applying of the bonding layer and the protective layer, the component substrate into the components, and
means for positioning, after the separating of the component substrate, the components on the carrier substrate, the components being fixed on the carrier substrate with the first component surface including the bonding layer,
means for processing, after the positioning of the components, the second component surface of each of the components, and
means for bonding, after the processing of the second component surface, the second component surface of each of the components on a product substrate.

15. (canceled)

16. The method according to claim 9, wherein the processing of the second component surface and the bonding of the second component surface are carried out under a vacuum such that the vacuum is maintained between the processing of the second component surface and the bonding of the second component surface

17. The device according to claim 13, wherein the means for preparing, the means for applying, the means for separating, and the means for positioning operate under a vacuum.

18. The device according to claim 14, wherein the means for preparing the components, the means for processing, and the means for bonding operate under a vacuum.

19. The device according to claim 18, wherein the carrier substrate is transferred between the means for preparing the components, the means for processing, and the means for bonding under the vacuum.
